(19) United States
(12) Patent Application Publication
(10) Pub. No.: US 2026/0204226 A1
(43) Pub. Date: Jul. 16, 2026

(54) DISPLAY DEVICE

(71) Applicant: LG Display Co., Ltd., Seoul (KR)

(72) Inventors: Ju Hong KIM, Paju-si (KR); Byeong Seong SO, Paju-si (KR)

(73) Assignee: LG Display Co., Ltd., Seoul (KR)

(21) Appl. No.: 19/431,163

(22) Filed: Dec. 23, 2025

(30) Foreign Application Priority Data
Dec. 30, 2024 (KR) 10-2024-0200631

(51) Int. Cl. G09G 3/3266; G09G 3/3275

(52) U.S. Cl. CPC G09G 3/3266; G09G 3/3275; G09G 2300/0819

(57) ABSTRACT

Embodiments disclose a display device including: a display panel including a display region where a plurality of pixels are disposed and a non-display region, a data driver that applies a data signal to the display panel, and a gate driver that applies a gate signal to the display panel, wherein each of the plurality of pixels includes a pixel circuit that drives a light-emitting element, and some of a plurality of switch elements of the pixel circuit are disposed in the non-display region.

### CROSS-REFERENCE TO RELATED APPLICATION

This application claims priority to and the benefit of Korean Patent Application No. 10-2024-0200631, filed on December 30, 2024, the disclosure of which is incorporated herein by reference in its entirety.

### BACKGROUND

### Technical Field

Embodiments relate to a display device.

### Description of Related Art

An organic light-emitting display device includes an organic light-emitting diode (hereinafter, referred to as “OLED”) which emits light by itself, and has an advantages of a quick response time, high luminous efficiency, high brightness, and a wide viewing angle. The organic light-emitting display device not only has a quick response time, excellent luminous efficiency, excellent brightness, and an excellent viewing angle, but also has an excellent contrast ratio and color reproducibility as black gradations may be expressed as true black.

A pixel circuit of the organic light-emitting display device includes an OLED, a driving element for driving the OLED, and a plurality of switch elements. In the pixel circuit, some switch elements are manufactured with oxide thin film transistors having excellent insulation performance, while other switch elements may be manufactured with low-temperature polycrystalline silicon (LTPS) transistors for quick response characteristics.

Polysilicon thin film transistors require an excimer laser annealing (ELA) crystallization process of crystalizing amorphous silicon. Accordingly, when there are polysilicon thin film transistors in both a pixel circuit in a display region and a gate driving circuit in a non-display region, since the ELA process should be performed on both the display region and the non-display region, there is a problem that a process size becomes larger.

### BRIEF SUMMARY

Embodiments are directed to a display device in which an excimer laser annealing (ELA) process is performed only in a non-display region.

The features of the present disclosure are not limited to the above-described objects, and other features that are not mentioned will be clearly understood by those skilled in the art from the following description.

A display device according to one embodiment of the present disclosure includes: a display panel including a display region where a plurality of pixels are disposed and a non-display region; a data driver that applies a data signal to the display panel; and a gate driver that applies a gate signal to the display panel, wherein each of the plurality of pixels includes a pixel circuit that drives a light-emitting element, and some of the plurality of switch elements in the pixel circuit are disposed in the non-display region.

The pixel circuit may include a driving element including a first electrode connected to a first node, a gate electrode connected to a second node, and a third electrode connected to a third node, and a 1-1 switch element that connects a first driving voltage line connected to a pixel driving voltage to the first node, and the 1-1 switch element may be disposed in the non-display region.

The first driving voltage line may extend from the non-display region to the display region and may be connected to the first node.

The first driving voltage line may extend from the non-display region to the display region and may be connected in common to driving elements of the plurality of pixels.

The driving element may be an oxide thin film transistor and the 1-1 switch element may be a polysilicon thin film transistor.

The display device may include a 1-2 switch element that connects the first node to a second driving voltage line connected to the pixel driving voltage, wherein the 1-2 switch element may be disposed in each pixel circuit.

The 1-1 switch element may apply the pixel driving voltage to the first node in response to a first EM signal, and the 1-2 switch element may apply the pixel driving voltage to the first node in response to a 1-2 EM signal that is synchronized with and has an opposite phase to the first EM signal.

The 1-1 switch element may be a polysilicon thin film transistor, and the 1-2 switch element may be an oxide thin film transistor.

The pixel circuit may include a second switch element that connects the second node to a reference voltage line; a third switch element that connects an anode of the light-emitting element to an initialization voltage line, and a fourth switch element that connects the second node to a data line, and the second to fourth switch elements may be oxide thin film transistors.

The pixel circuit may include a first capacitor in which one end is connected to the second node and the other end is connected to the third node, a second capacitor in which one end is connected to the third node and the other end is connected to the reference voltage line, and a sixth switch element that connects the second capacitor to the reference voltage line.

The gate driver may include a first emission signal driver that applies a first EM signal to the 1-1 switch element and the third switch element.

The gate driver may include a second emission signal driver that applies a 1-2 EM signal to the 1-2 switch element, and the 1-2 EM signal may have an opposite phase to the first EM signal.

The gate driver may include a third emission signal driver that applies an EM signal to the 1-1 switch element and the 1-2 switch element, the third emission signal driver may include a first output unit that outputs a first EM signal to the 1-1 switch element and a second output unit that outputs a 1-2 EM signal to the 1-2 switch element, and the 1-2 EM signal may have an opposite phase to the first EM signal.

A display device according to one aspect of the present disclosure includes: a display panel including a display region where a plurality of pixels are disposed and a non-display region; a data driver that applies a data signal to the display panel; and a gate driver that applies a gate signal to the display panel, wherein some switch elements of a pixel circuit of each of the plurality of pixels are disposed in the non-display region, all switch elements of the pixel circuit disposed in the display region are oxide thin film transistors, and the switch elements of the pixel circuits and the switch elements of the gate driver disposed in the non-display region are polysilicon thin film transistors.

### BRIEF DESCRIPTION OF THE SEVERAL VIEWS OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a view showing a display device according to one embodiment of the present disclosure;

FIG. 2 is a view showing a display panel according to one embodiment of the present disclosure;

FIG. 3 is a circuit diagram showing a pixel circuit according to one embodiment of the present disclosure;

FIG. 4 is a circuit diagram showing a pixel circuit according to another embodiment of the present disclosure;

FIG. 5 is a view showing a brightness deviation of the pixel circuit according to another embodiment of the present disclosure;

FIG. 6 is a waveform diagram of the pixel circuit according to another embodiment of the present disclosure;

FIG. 7A is a view showing the current flowing in the pixel circuit during an initialization operation;

FIG. 7B is a view showing the current flowing in the pixel circuit during a sampling operation;

FIG. 7C is a view showing the current flowing in the pixel circuit during a data writing operation;

FIG. 7D is a view showing the current flowing in the pixel circuit during an emission operation;

FIG. 8 is a view showing a gate driver according to one embodiment of the present disclosure;

FIG. 9 is a modified example of FIG. 8;

FIG. 10 is a view showing a gate driver according to another embodiment of the present disclosure;

FIG. 11 is a view showing a gate driver according to still another embodiment of the present disclosure;

FIG. 12 is a view showing an emission signal driver according to one embodiment of the present disclosure;

FIG. 13 is a waveform diagram of the emission signal driver according to one embodiment of the present disclosure;

FIG. 14 is a view showing an emission signal driver according to one embodiment of the present disclosure;

FIG. 15 is a waveform diagram of the emission signal driver according to one embodiment of the present disclosure;

FIG. 16 is a view showing an emission signal driver according to one embodiment of the present disclosure; and

FIG. 17 is a waveform diagram of the emission signal driver according to one embodiment of the present disclosure.

### DETAILED DESCRIPTION

Advantages and features of the present specification and methods of achieving them will become apparent with reference to the following embodiments, which are described in detail, in conjunction with the accompanying drawings. However, the present specification is not limited to the embodiments to be described below and may be implemented in various different forms, the embodiments are only provided to completely disclose the present specification and completely convey the scope of the present disclosure to those skilled in the art.

Since the shapes, sizes, proportions, angles, numbers, and the like disclosed in the drawings for describing the embodiments of the present specification are only exemplary, the present specification is not limited to the items shown in the drawings. The same reference number indicates the same components throughout the specification. Further, in describing the present specification, when it is determined that a detailed description of related known technology may unnecessarily obscure the gist of the present specification, the detailed description thereof will be omitted. When ‘providing,’ ‘including,’ ‘having,’ ‘consisting of,’ and the like mentioned in the present specification are used, other parts may be added unless ‘only’ is used. A case in which a component is expressed in a singular form may include a plural form unless explicitly stated otherwise.

In interpreting a component, the component is interpreted as including a margin of error even when there is no separate explicit description of the margin of error.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

In a description of a temporal relationship, when the temporal relationship is described as “after,” “following,” “and then,” “before,” or the like, non-consecutive cases may also be included unless “immediately” or “directly” is used.

Terms, such as first, second, A, B, (a), and (b) may be used to describe components of the present specification. These terms are only for the purpose of distinguishing one component from another component, and the nature, sequence, order, or the like of the corresponding components is not limited by these terms. When a component is described as being “connected,” “coupled,” or “linked,” to another component, it should be understood that the component may be directly connected or, linked to the other component, but another component may be “interposed” between the components which may be indirectly connected or linked to each other unless explicitly stated otherwise.

“At least one” should be understood as including a combination of one or more of the related components. For example, the term “at least one of first, second, and third components” includes not only the first, second, or third component, but also all combinations of two or more of the first, second, and third components.

Features of various embodiments of the present specification may be partially or entirely combined with each other, and technically, various linkages and operations are possible, and the embodiments may be implemented independently of each other or together in a related relationship.

Hereinafter, the embodiments of the present specification will be described with reference to the appended drawings and embodiments. The scale of the components shown in the drawings is different from the actual scale for convenience of description, and thus is not limited to the scale shown in the drawings.

Hereinafter, various embodiments of the present disclosure will be described in detail with reference to the accompanying drawings.

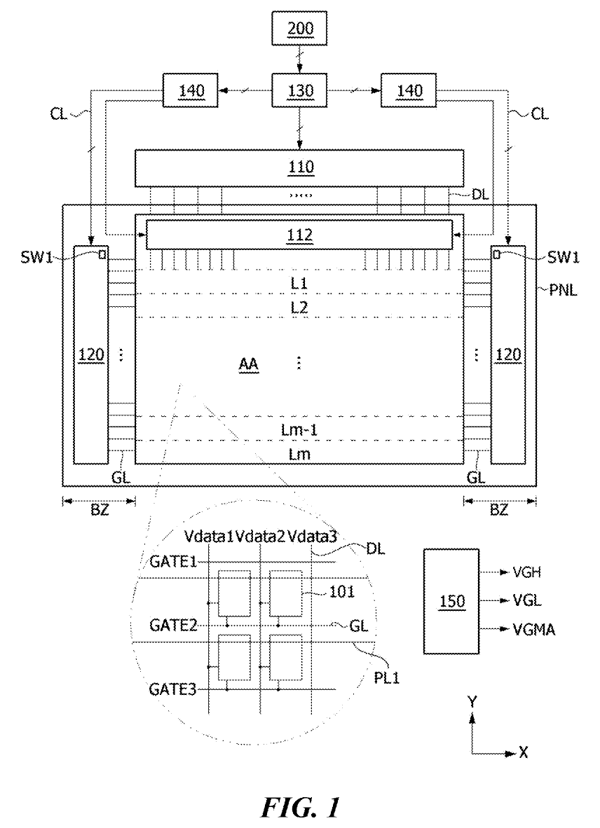

FIG. 1 is a view showing a display device according to an embodiment of the present disclosure.

Referring to FIG. 1, the display device according to the embodiment of the present disclosure includes a display panel PNL and a display panel driving circuit.

A display region AA of the display panel PNL includes a pixel array which displays pixel data of an input image. The pixel data of the input image is displayed in pixels of the pixel array. The pixel array includes a plurality of data lines DL, a plurality of gate lines GL intersecting the data lines DL, and pixels disposed in a matrix form. The arrangement of the pixels may be formed in various forms such as a form which shares pixels which emit light of the same color, a stripe form, a diamond form, and the like in addition to the matrix form.

When the resolution of the pixel array is n*m, the pixel array may include n pixel columns and m pixel lines L1 to Lm intersecting the pixel columns. The pixel line includes pixels disposed along a first direction. The pixel column includes pixels disposed along the first direction. One horizontal period 1H is the time acquired by dividing one frame period by the number of m pixel lines L1 to Lm. The pixel data is written to pixels of one pixel line in one horizontal period 1H.

Each of the pixels includes two or more sub-pixels 101 to implement a color. For example, each of the pixels may be divided into a red sub-pixel, a green sub-pixel, and a blue sub-pixel. Each of the pixels may further include a white sub-pixel. Each of the sub-pixels 101 may include a pixel circuit. The pixel circuit may include a pixel electrode, one or more thin film transistors TFT, and a capacitor. The pixel circuit is connected to data lines DL and gate lines GL.

Touch sensors may be disposed on the display panel 100 to implement a touch screen. A touch input may be sensed using separate touch sensors or may be sensed through the pixels. The touch sensors may be implemented as on-cell type or add on type sensors disposed on a screen of a display panel or in-cell type touch sensors built in the pixel array.

The display panel driving circuit may write data of the input image to the pixels of the display panel PNL under control of a timing controller 130. The display panel driving circuit may include a data driver 110, a gate driver 120, the timing controller 130 for controlling the operation timing of the drivers 110 and 120, a level shifter 140 connected between the timing controller 130 and the gate driver 120, and a power supply unit 150.

The data driver 110 converts the pixel data of the input image received as a digital signal from the timing controller 130 for each frame into an analog gamma compensation voltage and outputs data signals Vdata1 to Vdata3. The data signals Vdata1 to Vdata3 output from the data driver 110 are supplied to the data lines DL. The data driver 110 may output the data signals Vdata1 to Vdata3 using a digital to analog converter (hereinafter, referred to as “DAC”) which converts the digital signal into the analog gamma compensation voltage.

The display panel driving circuit may further include a demultiplexer array 112 disposed between the data driver 110 and the data lines DL.

The demultiplexer array 112 may sequentially connect one channel of the data driver 110 to the plurality of data lines DL to distribute a data signal output from one channel of the data driver 110 to the data lines DL in a time-division manner, thereby reducing the number of channels of the data driver110.

The gate driver 120 may be formed in a bezel region BZ where no image is displayed on the display panel 100, or at least a portion of the gate driver 120 may be disposed in the pixel array. The gate driver 120 receives a clock received from the level shifter 140 and outputs gate signals GATE. The gate signals GATE are supplied to the gate lines GL.

The gate signals GATE1 to GATE3 applied to the gate lines GL turn on the switch elements of the sub-pixels 101 to select the pixels in which voltages of the data signals Vdata1 to Vdata3 are charged. The switch elements of the sub-pixels 101 are turned on or off in response to the gate signals GATE1 to GATE3. The gate driver 120 shifts the gate signals using the shift register.

The timing controller 130 may control the operation timing of the display panel drivers 110 and 120 with a frame frequency of an input frame frequency x i (i is a positive integer greater than 0) Hz by multiplying an input frame frequency by i.

The timing controller 130 receives the pixel data of the input image and a timing signal synchronized with the pixel data from a host system 200. The pixel data of the input image received in the timing controller 130 is a digital signal. The timing controller 130 transmits the pixel data to the data driver 110. The timing signal includes a vertical synchronization signal Vsync, a horizontal synchronization signal Hsync, a clock signal CLK, a data enable signal DE, and the like. Since a vertical period and a horizontal period may be known by counting the data enable signal DE, the vertical synchronization signal Vsync and the horizontal synchronization signal Hsync may be omitted. The data enable signal DE may have a period of one horizontal period 1H.

The timing controller 130 may generate a data timing control signal for controlling the data driver 110, a gate timing control signal for controlling the gate driver 120, a control signal for controlling the switch elements of the demultiplexer array 112, and the like based on the timing signal received from the host system 200. The gate timing control signal may be generated as a clock of a digital signal voltage level.

The host system 200 may be any one of a television (TV), a set-top box, a navigation system, a personal computer (PC), a home theater, a mobile system, and a wearable system. In mobile devices and wearable devices, the data driver 110, the timing controller 130, the level shifter 140, and the like may be integrated into one drive integrated circuit (IC). In the mobile system, the host system 200 may be implemented as an application processor (AP).

The clock output from the level shifter 140 swings between a gate high voltage VGH and a gate low voltage VGL and is supplied to the gate driver 120 through clock lines CL. The clock output from the level shifter 140 may be applied to at least one of the demultiplexer array 112, the gate driver 120, and a touch sensor driver.

The power supply unit 150 generates a voltage required to drive the pixel array of the display panel 100 and the display panel driving circuit using a direct current (DC)-DC converter. The DC-DC converter may include a charge pump, a regulator, a buck converter, a boost converter, a buck-boost converter, and the like.

The power supply unit 150 may adjust a DC input voltage from the host system 200 to generate DC voltages such as a gamma reference voltage VGMA, the gate high voltage VGH, the gate low voltage VGL, a common voltage of the pixels, and the like. The gamma reference voltage VGMA may be supplied to the data driver 110. The gamma reference voltage VGMA may be divided by grayscale through a voltage dividing circuit of the data driver 110 and supplied to the DAC of the data driver 110. The power supply unit 150 may generate constant voltages applied to the pixels in common, for example, a common voltage Vcom, a pixel driving voltage EVDD, a pixel base voltage EVSS, and the like.

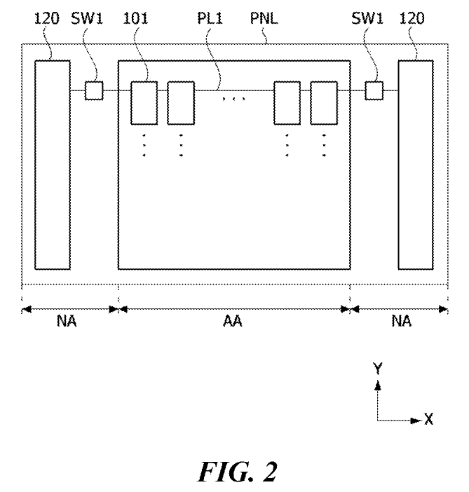

FIG. 2 is a view showing the display panel according to one embodiment of the present disclosure.

Referring to FIG. 2, in the display panel PNL according to the embodiment, some switch elements SW1 constituting the pixel circuit disposed in a display region AA may be disposed in a non-display region NA along with the gate driver 120. The switch element SW1 of the pixel circuit disposed in the non-display region NA may be a low temperature polycrystalline silicon (LTPS) thin film transistor (hereinafter referred to as a “polysilicon thin film transistor”).

The polysilicon thin film transistor has advantages of having a quick response time and excellent stability against temperature and light. However, excimer laser annealing (ELA) needs to be performed to form polysilicon. Excimer laser annealing (ELA) may be the most widely used crystallization method and may form polysilicon by irradiating pulsed ultraviolet (UV) light.

According to the embodiment, among the switch elements constituting the pixel circuit, since the polysilicon thin film transistors are disposed in the non-display region NA, there is an advantage that the excimer laser annealing process may be performed only in the non-display region NA. When the polysilicon thin film transistors are present in the display region AA, since the laser annealing process should be performed on the entire panel, there is a problem that manufacturing costs increase. Further, since the polysilicon thin film transistors and oxide thin film transistors are disposed together in the pixel, there is a problem that process complexity increases.

The switch element SW1 disposed in the non-display region NA may be a switch element which applies a pixel driving voltage. However, the embodiments are not limited thereto. For driving characteristics, the pixel circuit may include a plurality of polysilicon thin film transistors, and these polysilicon thin film transistors may be disposed in the non-display region NA.

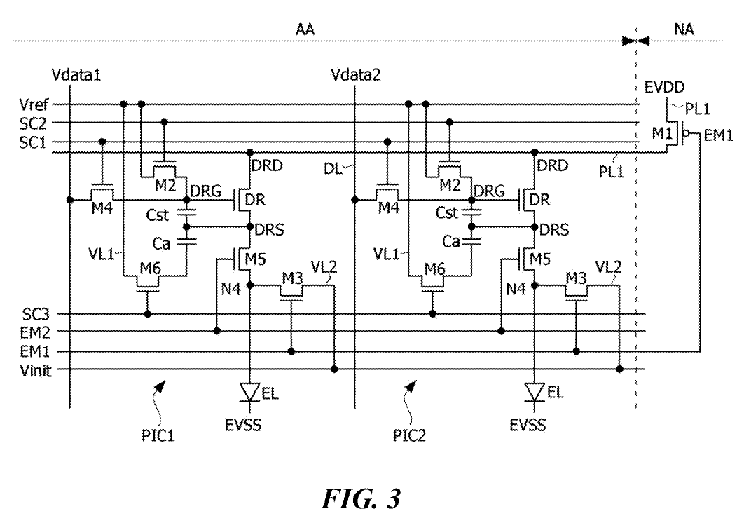

FIG. 3 is a circuit diagram showing the pixel circuit according to one embodiment of the present disclosure.

Referring to FIG. 3, neighboring first and second pixel circuits PIC1 and PIC2 may each include a light-emitting element EL, a driving element DR which supplies current to the light-emitting element EL, a plurality of switch elements M1, M2, M3, M4, M5, and M6, a first capacitor Cst, and a second capacitor Ca.

In the pixel circuit, the driving element DR and the second to sixth switch elements M2, M3, M4, M5, and M6 may be implemented as n-type oxide thin film transistors, and the first switch element M1 may be implemented as a p-type polysilicon thin film transistor. Accordingly, the driving element DR and the second to sixth switch elements M2, M3, M4, M5, and M6 may be turned on in response to the gate high voltage VGH, while the first switch element M1 may be turned on in response to the gate low voltage VGL.

The first switch element M1 may be disposed in the non-display region NA (a gate in panel (GIP) region) and may connect a driving voltage line PL1 to the driving element DR. The driving element DR of the first pixel circuit PIC1 and the driving element DR of the second pixel circuit PIC2 may be connected in common to the driving voltage line PL1 by the first switch element M1. Accordingly, when the first switch element M1 is turned on, the pixel driving voltage EVDD may be applied to the first pixel circuit PIC1 and the second pixel circuit PIC2. According to the embodiment, since the first switch element M1 is disposed in the non-display region NA and supplies the pixel driving voltage EVDD to the plurality of pixel circuits, the first switch element M1 may be omitted in each pixel circuit.

Constant voltages such as the pixel driving voltage EVDD, a low-potential power voltage ELVSS, a reference voltage Vref, an initialization voltage Vinit, and the like are applied to the pixel circuit. The light-emitting element EL may be implemented as an organic light-emitting diode (OLED). The OLED may include an organic compound layer formed between an anode and a cathode. The organic compound layer may include a hole injection layer HIL, a hole transport layer HTL, an emission layer EML, an electron transport layer ETL, an electron injection layer EIL, and the like, but the present disclosure is not limited thereto. The anode of the light-emitting element EL may be connected to a fourth node n4, and the cathode of the light-emitting element EL may be connected to a VSS node to which the low-potential power voltage ELVSS is applied.

When the voltage is applied to the anode and the cathode of the OLED, since holes passing through the hole transport layer HTL and electrons passing through the electron transport layer ETL move to the emission layer EML, excitons are formed. In this case, visible light may be emitted from the emission layer EML.

The driving element DR may include a gate electrode connected to a second node DRG, a first electrode connected to a first node DRD, and a third electrode connected to a third node DRS. Accordingly, a voltage applied to each electrode of the driving element DR may be the same as the voltages of the first to third nodes DRD, DRG, DRS.

The first capacitor Cst may have one end connected to the second node DRG and the other end connected to the third node DRS. The first capacitor Cst may store a gate-source voltage Vgs of the driving element DR. The second capacitor Ca may have one end connected to the third node DRS and the other end connected to a reference voltage line VL1.

The first capacitor Cst and the second capacitor Ca may determine a transfer rate of the data voltage Vdata at the gate-source voltage Vgs of the driving element DR according to a capacitance ratio. The capacitances of the first capacitor Cst and the second capacitor Ca may be appropriately selected according to a voltage range of the data voltage Vdata and the driving characteristics of the display panel PNL.

The first switch element M1 may be turned off in response to the gate high voltage VGH of a first EM signal EM1 and may block a current path between the driving voltage line PL1, to which the pixel driving voltage is applied, and the first node DRD during an initialization operation INIT and a data writing operation DW. The first switch element M1 may be turned on in response to the gate low voltage VGL of the first EM signal EM1 and may connect the driving voltage line PL1 to the first node DRD during a sampling operation SMPL and an emission operation EMI. The first switch element M1 may include a gate electrode to which the first EM signal EM1 is applied, a first electrode connected to the driving voltage line PL1, and a second electrode connected to the first node DRD.

The second switch element M2 may be turned on in response to the gate high voltage VGH of a second scan signal SC2 and may supply the reference voltage Vref to the second node DRG during the initialization operation INIT and the sampling operation SMPL. The second switch element M2 may include a gate electrode to which the second scan signal SC2 is applied, a first electrode connected to the reference voltage line VL1 to which the reference voltage Vref is applied, and a second electrode connected to the second node DRG.

The third switch element M3 may be turned on in response to the gate high voltage VGH of the first EM signal EM1 and may apply the initialization voltage Vinit to the fourth node n4 during the initialization operation INIT and an anode reset operation AR. The third switch element M3 may include a gate electrode to which a third scan signal SC3 is applied, a first electrode connected to the fourth node n4, and a second electrode connected to an initialization voltage line VL2 to which the initialization voltage Vinit is applied.

The fourth switch element M4 may be turned on in response to the gate high voltage VGH of a first scan signal SC1 and may supply the data voltage Vdata to the second node DRG during the data writing operation DW. The fourth switch element M4 may include a gate electrode to which the first scan signal SC1 is applied, a first electrode connected to the data line DL to which the data voltage Vdata is applied, and a second electrode connected to the second node DRG.

The fifth switch element M5 may be turned off in response to the gate low voltage VGL of a second EM signal EM2 and may block a current path between the third node DRS and the fourth node n4 during the sampling operation SMPL and the data writing operation DW. The fifth switch element M5 may be turned on in response to the gate high voltage VGH of the second EM signal EM2 and may form a current path between the driving element DR and the light-emitting element EL during the initialization operation INIT and the emission operation EMI. The fifth switch element M5 may include a gate electrode to which the second EM signal EM2 is applied, a first electrode connected to the third node DRS, and a second electrode connected to the fourth node n4.

The sixth switch element M6 may be turned on in response to the gate high voltage VGH of the third scan signal SC3 and may apply the reference voltage Vref to the second capacitor Ca during the sampling operation SMPL and the data writing operation DW.

The embodiment exemplifies a pixel circuit composed of seven transistors and two capacitors, but the embodiments of the present disclosure are not limited thereto. For example, the pixel circuit may be composed of four, five, or eight transistors, and may have one or two capacitors. That is, the pixel circuit of the embodiment may be applied to any pixel circuit including oxide thin film transistors and polysilicon thin film transistors, in which the polysilicon thin film transistors are disposed in the non-display region NA.

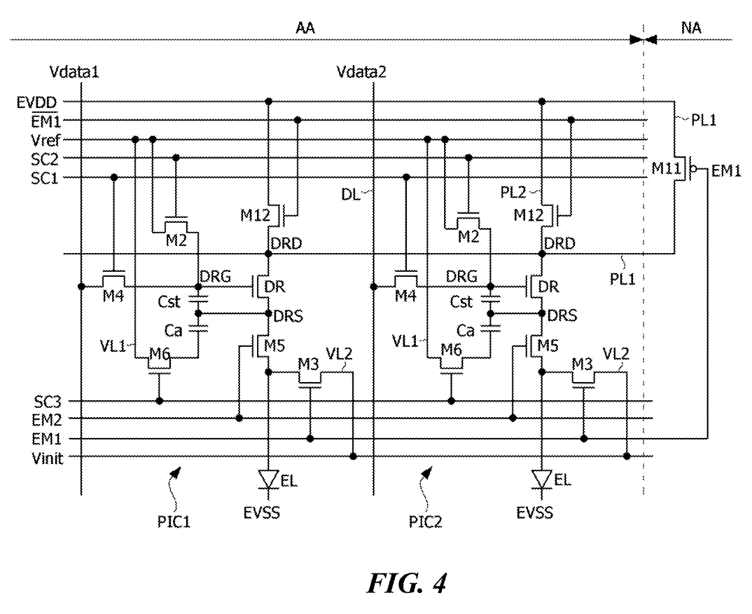

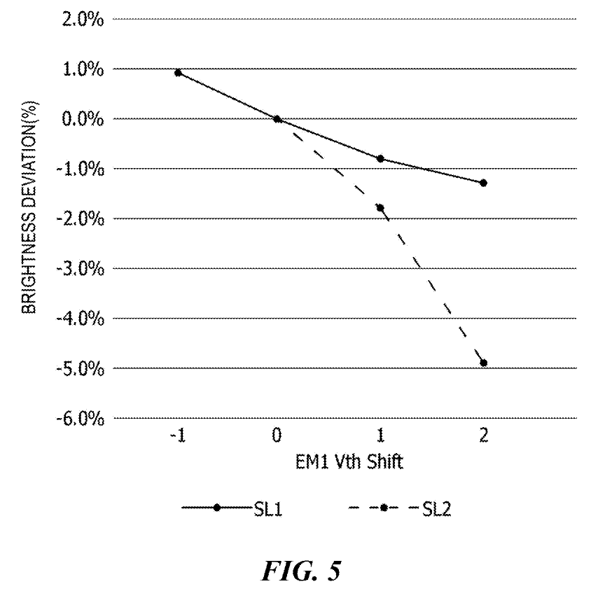

FIG. 4 is a circuit diagram showing a pixel circuit according to another embodiment of the present disclosure. FIG. 5 is a view showing a brightness deviation of the pixel circuit according to another embodiment of the present disclosure

Referring to FIG. 4, the pixel circuit according to the embodiment may include a 1-1 switch element M11 and a 1-2 switch element M12 connected to a pixel driving voltage EVDD. The 1-1 switch element M11 may be disposed in the non-display region NA and connected to the pixel circuit of the display region AA. The 1-2 switch element M12 may be disposed in each pixel circuit in the display region AA and may apply the pixel driving voltage EVDD to a driving element DR.

According to the embodiment, a first driving voltage line PL1 may be connected in common to a first node DRD of each driving element DR in a first pixel circuit PIC1 and a second pixel circuit PIC2. Further, a second driving voltage line PL2 may be connected to each driving element DR in the first pixel circuit PIC1 and the second pixel circuit PIC2.

The 1-1 switch element M11 may be a p-type polysilicon thin film transistor, and the 1-2 switch element M12 may be an n-type oxide thin film transistor. The 1-1 switch element M11 may apply the pixel driving voltage EVDD to the driving element DR in response to a first EM signal EM1. The 1-2 switch element M12 may apply the pixel driving voltage EVDD to the driving element DR in response to a 1-2 EM signal (EM1) ̅ which is an inverse phase signal of the first EM signal EM1.

According to the embodiment, since the pixel driving voltage EVDD may be applied to the driving element DR of each pixel circuit by the 1-2 switch element M12, an RC delay may be reduced depending on the position of the pixel. Since the 1-2 switch element M12 is an oxide thin film transistor, stress may occur and a threshold voltage may change due to the pixel driving voltage EVDD which is a relatively high voltage. However, according to the embodiment, since the pixel driving voltage EVDD is applied in an auxiliary manner by the 1-1 switch element M11, there is an advantage in that the output characteristics of the pixel driving voltage EVDD may be stably maintained.

Referring to FIG. 5, when comparing a brightness deviation measurement result SL1 of the case in which both the 1-1 and 1-2 switch elements are present and a brightness deviation measurement result SL2 of the case in which only the 1-2 switch element is present, it can be seen that the brightness deviation is smaller when both the 1-1 and 1-2 switch elements are present. An X-axis is a measurement result of a fluctuation of the threshold voltage based on the case in which the change in the threshold voltage is ‘0’, and a Y-axis is a measurement result of a change in brightness based on brightness (0.0%) in the case in which the change in the threshold voltage is ‘0’.

When the threshold voltage of the 1-2 switch element M12 changes due to stress, a kickback deviation of the pixel driving voltage due to the threshold voltage fluctuation of the 1-2 switch element M12 may be reduced by the 1-1 switch element M11. Accordingly, the brightness deviation may be reduced by reducing a fluctuation of a DRS node.

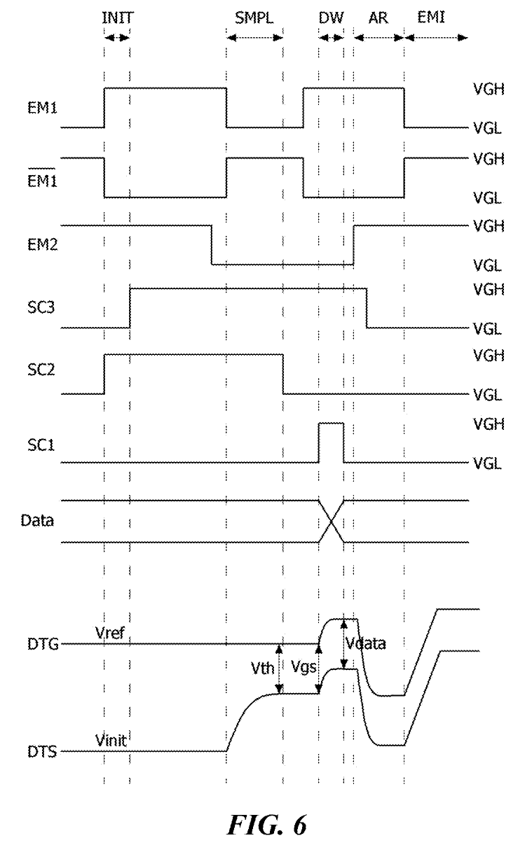

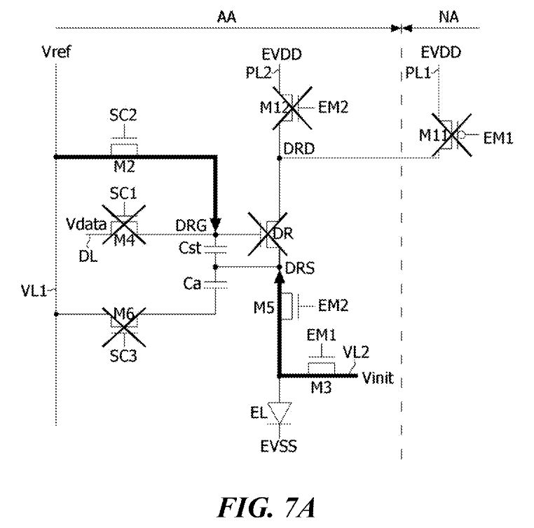

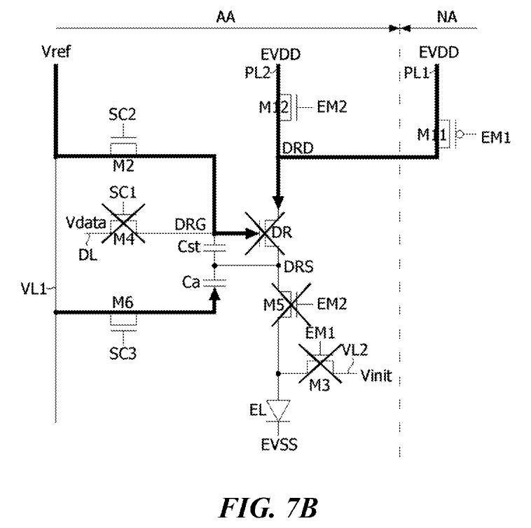

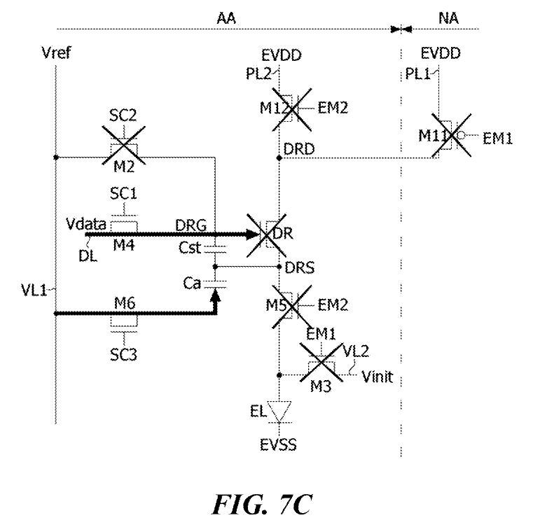

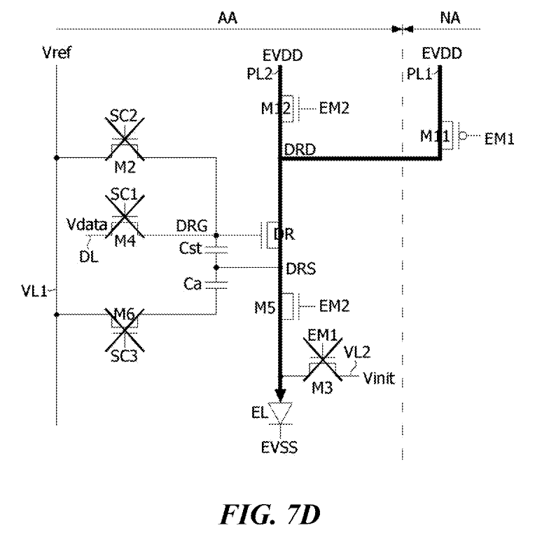

FIG. 6 is a waveform diagram showing a driving method of the pixel circuit according to another embodiment of the present disclosure. FIGS. 7A to 7D are views showing the current flowing in the pixel circuit during a refresh operation.

Referring to FIGS. 6 and 7A, during an initialization operation INIT, second, third, and fifth switch elements M2, M3, and M5 may be turned on. During the initialization operation INIT, a 1-1 switch element M11, a 1-2 switch element M12, and a fourth switch element M4 may be turned off.

Referring to FIGS. 6 and 7B, during a sampling operation SMPL, the 1-1 switch element M11, the 1-2 switch element M12, the second switch element M2, and a sixth switch element M6 may be turned on, while the other switch elements M3, M4, and M5 may be turned off. During the sampling operation SMPL, when a voltage at the third node DRS rises and thus a gate-source voltage Vgs of the driving element DR reaches a threshold voltage Vth, the driving element DR may be turned off. When the sampling operation SMPL ends, voltages of major nodes are DRD=EVDD, DRG=Vref, and DRS=Vref-Vth. Accordingly, when the sampling operation SMPL ends, the gate-source voltage Vgs of the driving element DR is Vgs = Vth. The sampled threshold voltage Vth of the driving element DR may be charged to a first capacitor Cst.

Referring to FIGS. 6 and 7C, during a data writing operation DW, since the fourth switch element M4 and the sixth switch element M6 are turned on, a data voltage Vdata of pixel data may be applied to the second node DRG. In this case, the other switch elements M11, M12, M2, M3, and M5 may be turned off. When the data writing operation DW ends, the voltages of the major nodes may change to DRD = EVDD, DRG = Vdata, and DRS = Vref - Vth + C′ × (Vdata - Vref). Here, C′ = Cst / (Cst + Ca).

Referring to FIGS. 6 and 7D, during an emission operation EMI, the 1-1 switch element M11, the 1-2 switch element M12, and the fifth switch element M5 may be turned on, while the other switch elements M2, M3, M4, and M6 may be turned off. According to the embodiment, during the emission operation EMI, the pixel driving voltage may be simultaneously applied by the 1-1 switch element M11 and the 1-2 switch element M12.

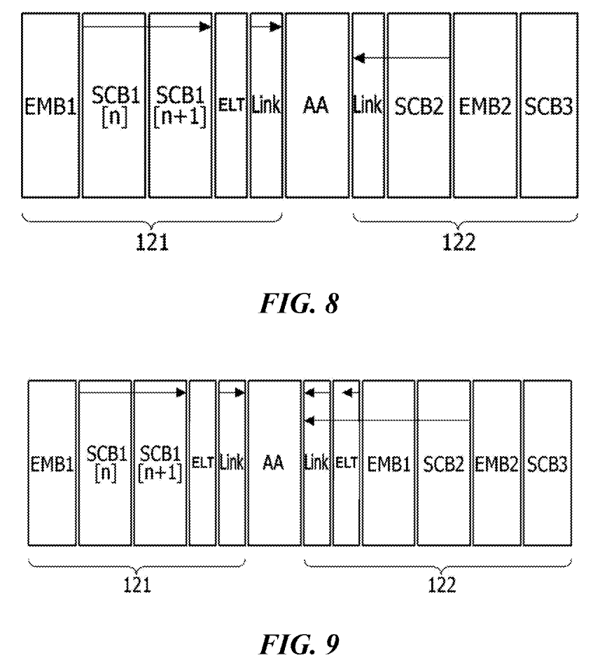

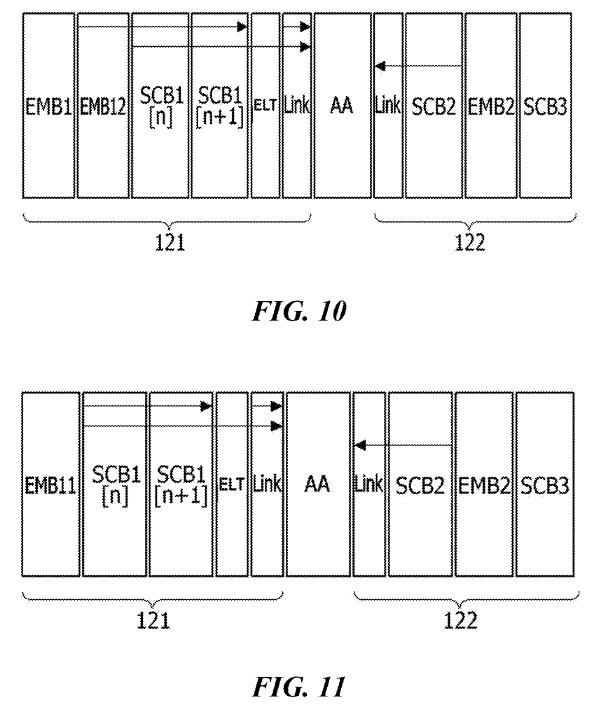

FIG. 8 is a view showing a gate driver according to one embodiment of the present disclosure. FIG. 9 is a modified example of FIG. 8. FIG. 10 is a view showing a gate driver according to another embodiment of the present disclosure. FIG. 11 is a view showing a gate driver according to still another embodiment of the present disclosure.

Referring to FIG. 8, a first gate driver 121 may be disposed on a left side and a second gate driver 122 may be disposed on a right side based on the display region AA. FIG. 8 is a block diagram of the gate driver connected to the pixel circuit in FIG. 3.

The first gate driver 121 may include a first EM region EMB1, a first scan region SCB1, and a first switch region ELT. The first switch area ELT may be an area where the first switch element M1 is arranged. The first EM region EMB1 may apply an EM signal to the first switch region ELT. The first scan region SCB1 may apply a first scan signal to the display region AA. The first EM region EMB1, the first scan region SCB1, and the first switch region ELT may be sequentially disposed from the outside of the display device in a direction in which the display region AA is disposed.

The second gate driver 122 may include a third scan region SCB3, a second EM region EMB2, and a second scan region SCB2. The third scan region SCB3, the second EM region EMB2, and the second scan region SCB2 may be sequentially disposed from the outside of the display device in the direction in which the display region AA is disposed.

In the embodiment, the first to third scan signals, and a second EM signal may be signals provided to the oxide thin film transistor included in the pixel circuit. The first EM signal may be a signal provided to the first switch element M1 disposed in the non-display region NA. A link region Link may be disposed between the display region AA and the gate driver 120. The reference voltage Vref line, the initialization voltage Vini line, and the like may be disposed in the link region Link. Referring to FIG. 9, in a double feeding structure in which the first switch elements M1 are disposed on both sides of the display region, the first switch region ELT and the first EM region EMB1 may be disposed on both sides of the display region AA.

FIG. 10 is a block diagram of a gate driver connected to the pixel circuit in FIG. 4. Referring to FIG. 10, a first gate driver 121 may include a first EM region EMB1, a 1-2 EM region EMB12, a first scan region SCB1, and a first switch region ELT. The first EM region EMB1 may apply an EM signal to the first switch region ELT. The 1-2 EM region EMB12 may apply a 1-2 EM signal to a 1-2 switch element M12 in the display region AA. The 1-2 EM signal may have an opposite phase to the first EM signal.

The first scan region SCB1 may apply a first scan signal to the display region AA. The first EM region EMB1, the 1-2 EM region EMB12, the first scan region SCB1, and the first switch region ELT may be sequentially disposed from the outside of the display device in the direction in which the display region AA is disposed.

A second gate driver 122 may include a third scan region SCB3, a second EM region EMB2, and a second scan region SCB2. The third scan region SCB3, the second EM region EMB2, and the second scan region SCB2 may be sequentially disposed from the outside of the display device in the direction in which the display region AA is disposed.

In the embodiment, the first to third scan signals, and a second EM signal may be signals provided to the driving element DR, the 1-2 switch element M12, and second to sixth switch elements M2, M3, M4, M5, and M6 included in the pixel circuit. The first EM signal may be a signal provided to the 1-1 switch element M11 disposed in the non-display region NA.

FIG. 11 is a block diagram of a gate driver connected to the pixel circuit in FIG. 4. Referring to FIG. 11, a first gate driver 121 may include a 1-1 EM region EMB11, a first scan region SCB1, and a first switch region ELT. The 1-1 EM region EMB11 may apply a first EM signal to the 1-1 switch element M11 in the first switch region ELT and a 1-2 EM signal to the 1-2 switch element M12 in the display region AA. The 1-2 EM signal may have an opposite phase to the first EM signal.

The first scan region SCB1 may apply a first scan signal to the display region AA. The 1-1 EM region EMB11, the first scan region SCB1, and the first switch region ELT may be sequentially disposed from the outside of the display device in the direction in which the display region AA is disposed.

A second gate driver 122 may include a third scan region SCB3, a second EM region EMB2, and a second scan region SCB2. The third scan region SCB3, the second EM region EMB2, and the second scan region SCB2 may be disposed sequentially from the outside of the display device in the direction in which the display region AA is disposed.

In the embodiment, the first to third scan signals, and a second EM signal may be signals provided to the oxide thin film transistor included in the pixel circuit. The first EM signal may be a signal provided to the 1-1 switch element M11 disposed in the non-display region NA.

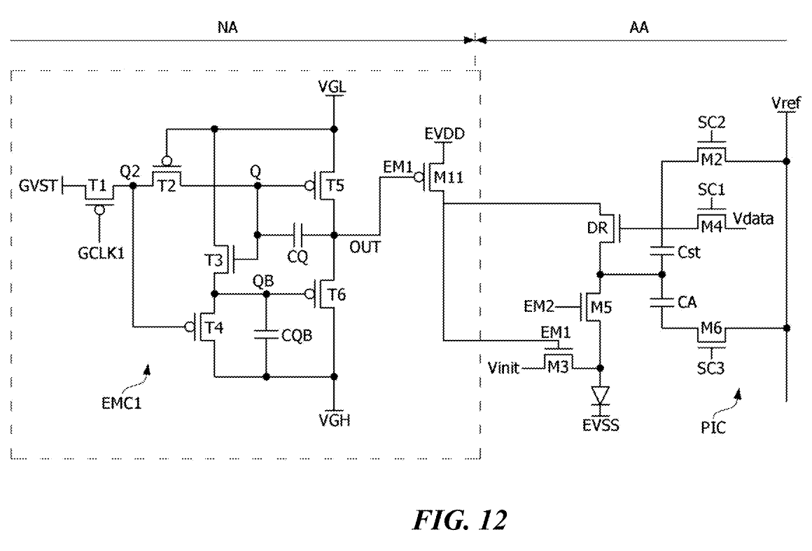

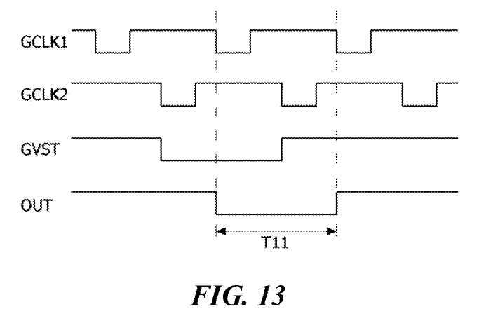

FIG. 12 is a view showing an emission signal driver according to one embodiment of the present disclosure. FIG. 13 is a waveform diagram of the emission signal driver according to one embodiment of the present disclosure.

An emission signal driver EMC1 may include first to sixth transistors T1, T2, T3, T4, T5, and T6, a third capacitor CQ and a fourth capacitor CQB. In the first transistor T1, a first electrode may be connected to an input terminal of a start signal GVST, a gate electrode may be connected to a supply line of a first clock signal GCLK1, and a second electrode may be connected to a third node Q2.

In the second transistor T2, a first electrode may be connected to the third node Q2, a gate electrode may be connected to a supply line of the gate low voltage VGL, and a second electrode may be connected to a first node Q.

In the third transistor T3, a first electrode may be connected to a supply line of the gate low voltage VGL, a gate electrode may be connected to the first node Q, and a second electrode may be connected to a second node QB. The third transistor T3 may be turned on by a voltage of the first node Q and may apply the gate low voltage VGL to the second node QB.

In the fourth transistor T4, a first electrode may be connected to the second node QB, a gate electrode may be connected to the third node Q2, and a second electrode may be connected to a supply line of the gate high voltage VGH. The fourth transistor T4 may be turned on by a voltage of the third node Q2 and may apply the gate high voltage VGH to the second node QB.

In the fifth transistor T5, since a first electrode is connected to the supply line of the gate low voltage VGL, a gate electrode is connected to the first node Q, and a second electrode is connected to an output terminal OUT, the fifth transistor T5 may be turned on or turned off depending on the voltage of the first node Q and may output the gate low voltage VGL to the output terminal OUT.

In the sixth transistor T6, since a first electrode is connected to the supply line of the gate high voltage VGH, a gate electrode is connected to the second node QB, and a second electrode is connected to the output terminal OUT, the sixth transistor T6 may be turned on or off depending on a voltage of the second node QB and may output the gate high voltage VGH to the output terminal OUT.

The third capacitor CQ may be coupled between the first node Q and the output terminal OUT, and the fourth capacitor CQB may be coupled between the second node QB and the gate high voltage VGH.

The first transistor T1, the second transistor T2, the fourth transistor T4, the fifth transistor T5, and the sixth transistor T6 may be p-type polysilicon thin film transistors, and the third transistor T3 may be an n-type polysilicon thin film transistor.

In a first output section T11, when an output signal of the start signal GVST is input at a low level and the first clock signal GCLK1 is applied as the gate low voltage VGL, since the first and second transistors T1 and T2 are turned on, the first node Q and the third node Q2 may be charged with the gate low voltage.

When the first node Q and the third node Q2 are charged with the gate low voltage VGL, since the third transistor T3 is turned off and the fourth transistor T4 is turned on, the second node QB may be charged with the gate high voltage VGH.

The fifth transistor T5 may be turned on when the gate low voltage VGL is input to the gate electrode, and the sixth transistor T6 may be turned off when the gate low voltage VGL is input to the gate electrode. Accordingly, the fifth transistor T5 may output the gate low voltage VGL to the 1-1 switch element M11 of a pixel circuit PIC. On the other hand, when the fifth transistor T5 is turned off and the sixth transistor T6 is turned on, the gate high voltage VGH may be output.

Since the gate low voltage VGL is output to a gate electrode of a first switch element M1 of the pixel circuit PIC, the first switch element M1 of the pixel circuit PIC may be turned on and may apply the pixel driving voltage EVDD to the driving element DR.

According to the embodiment, since the gate driving circuit and the first switch element M1 of the pixel circuit are both disposed in the non-display region NA, an excimer laser annealing (ELA) process may be performed only in the non-display region NA.

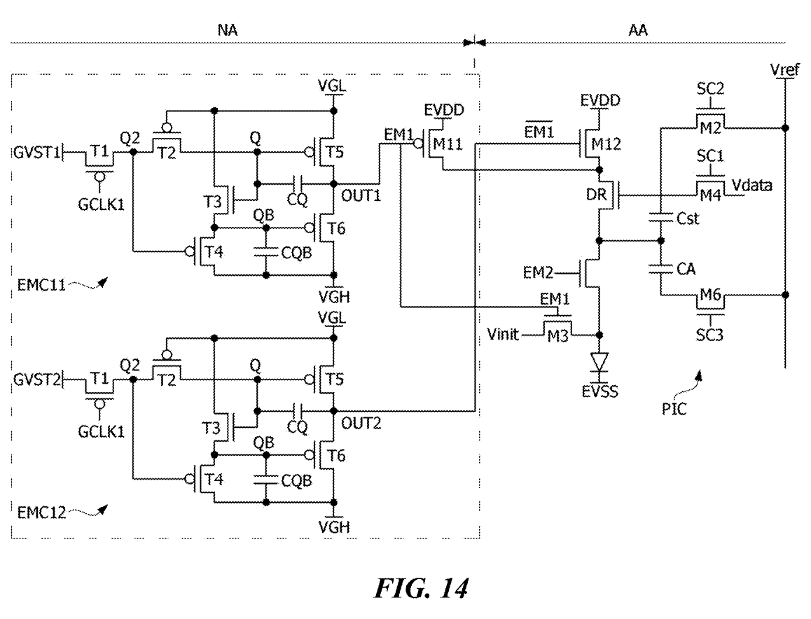

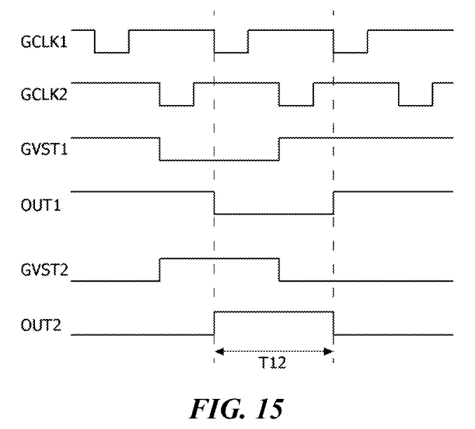

FIG. 14 is a view showing an emission signal driver according to one embodiment of the present disclosure. FIG. 15 is a waveform diagram of the emission signal driver according to one embodiment of the present disclosure.

Referring to FIGS. 14 and 15, in the pixel circuit PIC, the 1-1 switch element M11 may be disposed in the non-display region NA and the 1-2 switch element M12 may be disposed in the display region AA. The emission signal driver may include a first emission signal driver EMC11 which applies an output voltage to the 1-1 switch element M11 and a second emission signal driver EMC12 which applies an output voltage to the 1-2 switch element M12.

The 1-1 switch element M11 may be a p-type polysilicon thin film transistor and the 1-2 switch element M12 may be an n-type oxide thin film transistor. In the second output section T12, the first emission signal driver EMC11 may output a gate low voltage and the second emission signal driver EMC12 may output a gate high voltage to simultaneously turn on the 1-1 switch element M11 and the 1-2 switch element M12. The output voltages of the first emission signal driver may be simultaneously applied to the third switch element M3 of the pixel circuit PIC.

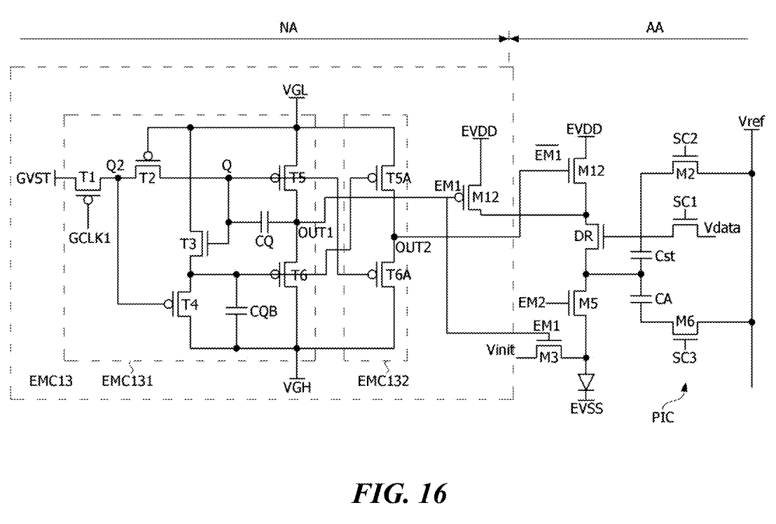

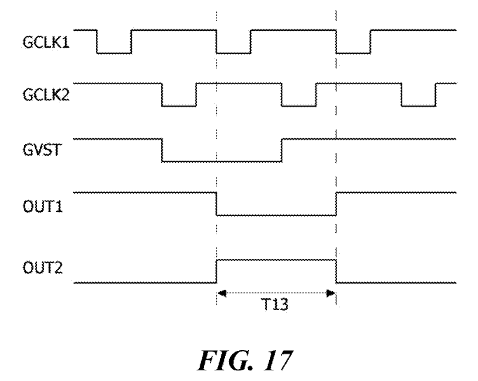

FIG. 16 is a view showing an emission signal driver according to one embodiment of the present disclosure. FIG. 17 is a waveform diagram of the emission signal driver according to one embodiment of the present disclosure.

Referring to FIGS. 16 and 17, a third emission signal driver EMC13 may include a first driving region EMC131 which applies a gate low voltage to the 1-1 switch element M11 and a second driving region EMC132 which applies a gate high voltage to the 1-2 switch element M12.

The first driving region EMC131 may have the same structure as the emission signal driver described in FIG. 14. The second driving region EMC132 may include a seventh transistor T5A and an eighth transistor T5B.

The seventh transistor T5A may include a first electrode connected to the gate low voltage VGL, a gate electrode connected to the sixth transistor T6, and a second electrode connected to a second output terminal OUT2. Accordingly, the seventh transistor T5A may output a signal having an opposite phase to the output signal of the fifth transistor T5.

The eighth transistor T5B may include a first electrode connected to the gate high voltage VGH, a gate electrode connected to the fifth transistor T5, and a second electrode connected to the second output terminal OUT2. Accordingly, the eighth transistor T5B may output a signal having an opposite phase to the output signal of the sixth transistor T6.

According to the embodiment, in a third output period T13, the first driving region EMC131 and the second driving region EMC132 may simultaneously turn on the 1-1 switch element M11 and the 1-2 switch element M12 by sharing a switch part and separating the output terminals OUT1 and OUT2. Thereafter, the 1-1 switch element M11 and the 1-2 switch element M12 may be simultaneously turned off.

According to an embodiment, since an excimer laser annealing (ELA) process is performed only in a non-display region, a display device can be manufactured at low cost.

Effects of the present disclosure are not limited to the above-mentioned effects, and other effects which are not mentioned will be clearly understood by those skilled in the art from the description herein.

The contents of the specification described in the problem to be solved, the means for solving the problem, and the effects described above do not specify the features of the claims, and the scope of the claims is not limited by the items described in the contents of the specification.

Although the embodiments of the present disclosure have been described in more detail with reference to the accompanying drawings, the present disclosure is not necessarily limited to these embodiments, and may be variously modified without departing from the technical spirit of the present disclosure. Accordingly, the embodiments disclosed in the present disclosure are not intended to limit the technical spirit of the present disclosure, but intended to describe the same, and the scope of the technical spirit of the present disclosure is not limited by these embodiments. Accordingly, it should be understood that the above-described embodiments are illustrative and not restrictive in all respects.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel including a display region where a plurality of pixels are disposed and a non-display region;
a data driver configured to apply a data signal to the display panel; and
a gate driver configured to apply a gate signal to the display panel,
wherein each of the plurality of pixels includes a pixel circuit configured to drive a light-emitting element, the pixel circuit including a plurality of switch elements, and
at least one of the plurality of switch elements of the pixel circuit is disposed in the non-display region.

2. The display device of claim 1, wherein the pixel circuit includes a driving element including a first electrode connected to a first node, a gate electrode connected to a second node, and a third electrode connected to a third node, and the plurality of switch elements include a 1-1 switch element that connects a first driving voltage line connected to a pixel driving voltage to the first node, and
the 1-1 switch element is disposed in the non-display region.

3. The display device of claim 2, wherein the first driving voltage line extends from the non-display region to the display region and is connected to the first node.

4. The display device of claim 3, wherein the first driving voltage line extends from the non-display region to the display region and is connected in common to driving elements of the plurality of pixels.

5. The display device of claim 2, wherein the driving element is an oxide thin film transistor and the 1-1 switch element is a polysilicon thin film transistor.

6. The display device of claim 2, wherein the plurality of switch elements include a 1-2 switch element that connects the first node to a second driving voltage line connected to the pixel driving voltage,
wherein the 1-2 switch element is disposed in each pixel circuit.

7. The display device of claim 6, wherein the 1-1 switch element is configured to apply the pixel driving voltage to the first node in response to a first EM signal, and
the 1-2 switch element is configured to apply the pixel driving voltage to the first node in response to a 1-2 EM signal that is synchronized with and has an opposite phase to the first EM signal.

8. The display device of claim 6, wherein the 1-1 switch element is a polysilicon thin film transistor, and the 1-2 switch element is an oxide thin film transistor.

9. The display device of claim 6, wherein the plurality of switch elements include:
a second switch element that connects the second node to a reference voltage line;
a third switch element that connects an anode of the light-emitting element to an initialization voltage line; and
a fourth switch element that connects the second node to a data line, and
the second to fourth switch elements are oxide thin film transistors.

10. The display device of claim 9, wherein the pixel circuit includes:
a first capacitor in which one end is connected to the second node and the other end is connected to the third node;
a second capacitor in which one end is connected to the third node and the other end is connected to the reference voltage line; and
the plurality of switch elements include a sixth switch element that connects the second capacitor to the reference voltage line.

11. The display device of claim 9, wherein the gate driver includes a first emission signal driver configured to apply a first EM signal to the 1-1 switch element and the third switch element.

12. The display device of claim 11, wherein the gate driver includes a second emission signal driver configured to apply a 1-2 EM signal to the 1-2 switch element, and
the 1-2 EM signal has an opposite phase to the first EM signal.

13. The display device of claim 9, wherein the gate driver includes a third emission signal driver configured to apply an EM signal to the 1-1 switch element and the 1-2 switch element,
the third emission signal driver includes a first output unit configured to output a first EM signal to the 1-1 switch element and a second output unit configured to output a 1-2 EM signal to the 1-2 switch element, and
the 1-2 EM signal has an opposite phase to the first EM signal.

14. A display device comprising:
a display panel including a display region where a plurality of pixels are disposed and a non-display region;
a data driver configured to apply a data signal to the display panel; and
a gate driver configured to apply a gate signal to the display panel,
wherein a pixel circuit of each of the plurality of pixels includes one or more polysilicon thin film transistors disposed in the non-display region, and one or more oxide thin film transistors disposed in the display region, and
the gate driver includes one or more polysilicon thin film transistors disposed in the non-display region.

15. The display device of claim 14, wherein the pixel circuit includes:
a driving element including a first electrode connected to a first node, a gate electrode connected to a second node, and a third electrode connected to a third node;
a 1-1 switch element that connects the first node to a first driving voltage line connected to a pixel driving voltage;
a 1-2 switch element that connects the first node to a second driving voltage line connected to the pixel driving voltage;
a second switch element that connects the second node to a reference voltage line;
a third switch element that connects an anode of a light-emitting element to an initialization voltage line; and
a fourth switch element that connects the second node to a data line,
wherein the 1-1 switch element is a polysilicon thin film transistor of the one or more polysilicon thin film transistors disposed in the non-display region, and
wherein the second to fourth switch elements are oxide thin film transistors of the one or more oxide thin film transistors disposed in the display region.
